(19) United States
(12) Patent Application Publication
(10) Pub. No.: US 2026/0245610 A1
(43) Pub. Date: Aug. 20, 2026

(54) APPARATUS INCLUDING SENSE AMPLIFIER AND ISOLATION TRANSISTOR

(71) Applicant: Micron Technology, Inc., Boise, ID (US)

(72) Inventors: Kenji Asaki, Sagamihara-shi (JP); Yoshifumi Mochida, Sagamihara (JP)

(21) Appl. No.: 19/532,924

(22) Filed: Feb. 6, 2026

Related U.S. Application Data
(60) Provisional application No. 63/760,832, filed on Feb. 20, 2025.

(51) Int. Cl. G11C 11/4091; G11C 11/4074; G11C 11/408; G11C 11/4094

(52) U.S. Cl. CPC G11C 11/4091; G11C 11/4074; G11C 11/4082; G11C 11/4094

(57) ABSTRACT

Some embodiments of the disclosure provide an apparatus comprising an isolation (ISO) transistor of a sense amplifier. The ISO transistor has a gate at a first voltage level during a sense phase and at a second voltage level during a standby phase. The second voltage level is lower than the first voltage level. This reduces gate leak current during the standby phase and improves current consumption. The apparatus may have a level select circuit configured to select the first voltage level during the sense phase and the second voltage level during the standby phase in response to a level select signal, which in some instances may be a first level at a sense timing and a second level at a precharge timing.

### CROSS-REFERENCE TO RELATED APPLICATIONS

This application claims the filing benefit of U.S. Provisional Application No. 63/760,832, filed February 20, 2025. This application is incorporated by reference herein in its entirety and for all purposes.

### BACKGROUND

High data reliability, high speed of memory access, low power consumption, and reduced chip size are some features that are demanded from semiconductor memory devices, such as a dynamic random-access memory (DRAM). A memory device may include a plurality of memory cells located at intersections of word lines arranged in rows and bit (or digit) lines arranged in columns. Each memory cell may include a capacitor to store data and a transistor to access the capacitor. A memory device may further include sense amplifiers that sense and amplify data read from memory cells of bit lines on associated columns of a selected row.

### BRIEF DESCRIPTION OF THE DRAWINGS

FIG. 1 is a block diagram of an example semiconductor device according to some embodiments of the disclosure.

FIG. 2 is a circuit diagram of at least part of an example sensing amplifier according to some embodiments of the disclosure.

FIGS. 3A is a schematic diagram of at least part of an example apparatus according to some embodiments of the disclosure.

FIG. 3B is a timing diagram of an ISO voltage level operation according to some embodiments of the disclosure.

FIGS. 3C and 3D each are a schematic diagram of at least part of an example apparatus according to some embodiments of the disclosure.

### DETAILED DESCRIPTION

Various example embodiments of the disclosure and combinations thereof will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

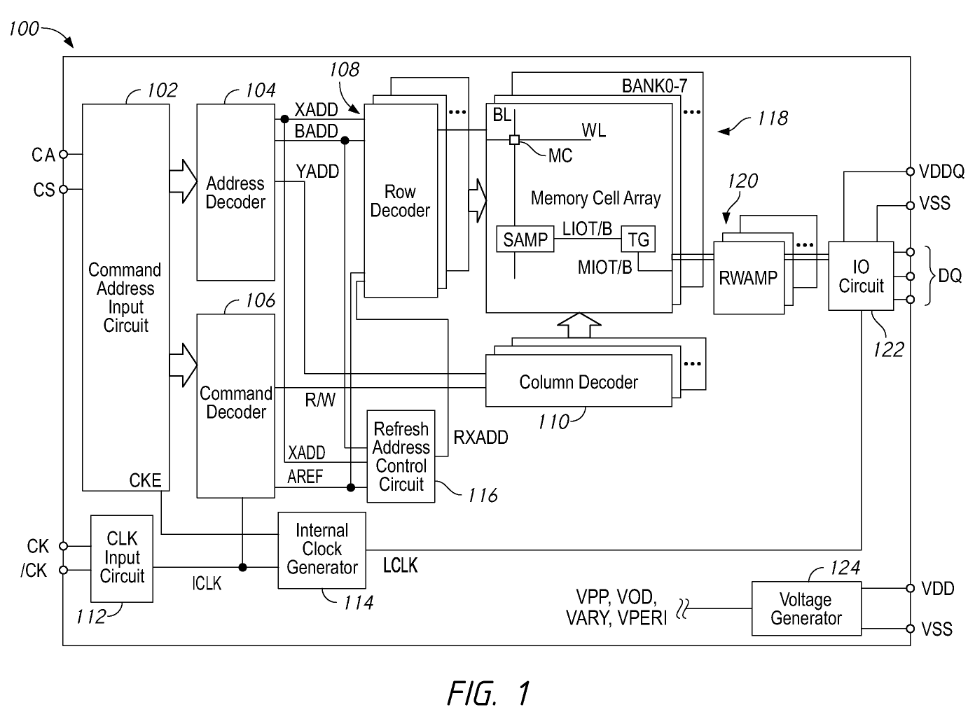

FIG. 1 is a block diagram of an example semiconductor device 100 according to some embodiments of the disclosure. The semiconductor device 100 may be one example of an apparatus. The semiconductor device 100 may be a semiconductor memory device, such as a dynamic random access memory (DRAM). The semiconductor device 100 includes a memory array 118. The memory array 118 is shown as including a plurality of memory banks. In the depicted example, the memory array 118 is shown as including eight memory banks BANK0-BANK7. More or fewer banks may be included in the memory array 118. Each memory bank includes a plurality of word lines WL, a plurality of bit lines BL (or digit lines DL), and a plurality of memory cells MC arranged at intersections of the plurality of word lines WL and the plurality of bit line BL. Selection of the word line WL is performed by a row decoder 108 and selection of the bit lines BL is performed by a column decoder 110. In the depicted example, the row decoder 108 includes a respective row decoder for each memory bank and the column decoder 110 includes a respective column decoder for each memory bank. The bit lines BL are coupled to a respective sense amplifier SAMP of the memory array 118. Read data from the bit line BL is amplified by the sense amplifier SAMP, and transferred to a respective read/write amplifier (RWAMP) 120 for each memory bank over complementary local input/output data lines LIOT/B (LIO True/Bar (False)), a transfer gate TG, and complementary main (or global) input/output data lines MIOT/B (MIO True/Bar (False)) which are coupled to RWAMP 120. Conversely, write data outputted from RWAMP 120 for each memory bank is transferred to the sense amplifier SAMP over the complementary main input/output data lines MIOT/B, the transfer gate TG, and the complementary local input/output data lines LIOT/B, and written in the memory cell MC coupled to the bit line BL.

The semiconductor device 100 may employ a plurality of external terminals. The external terminals may include command and address (CA) terminals coupled to a command and address bus to receive commands and addresses and a chip select (CS) signal, clock terminals to receive clocks CK and /CK, data terminals DQ to provide data, and power supply terminals to receive power supply potentials VDD, VSS, and VDDQ.

The clock terminals are supplied with external clocks CK and /CK that are provided to an input circuit 112. The external clocks CK and /CK may be complementary. The input circuit 112 generates an internal clock ICLK based on the CK and /CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal clocks LCLK are provided to an input and output (IO) circuit 122 to time operation of circuits included in the IO circuit 122, for example, to data receivers to time the receipt of write data. In some embodiments, the internal clocks LCLK may include a read clock which is used to control the timing of read operations, and a write clock which is used to control the timing of write operations. In some embodiments, the internal clocks may be passed to the IO circuit 122. In some embodiments, the internal clocks may also be passed to internal components, such as RWAMP 120.

The CA terminals may be supplied with memory addresses. The memory addresses supplied to the CA terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The CA terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to the command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The semiconductor device 100 may receive an access command which is a read command. When a read command is received, and a bank address, a row address and a column address are timely supplied with an activate command and the read command, read data is read from memory cells in the memory array 118 corresponding to the row address and column address. The read command is received by the command decoder 106, which provides internal commands so that the read data from the memory cells in the memory array 118 is provided to RWAMP 120. The read data is output to outside the semiconductor device 100 from the data terminals DQ via the IO circuit 122.

The semiconductor device 100 may receive an access command which is a write command. When the write command is received, and a bank address, a row address and a column address are timely supplied with an activate command and the write command, write data is supplied through the DQ terminals to RWAMP 120. The write data supplied to the data terminals DQ is written to the memory cells in the memory array 118 corresponding to the row address and column address. The write command is received by the command decoder 106, which provides internal commands so that the write data is received by data receivers in the IO circuit 122. Write clocks may also be provided to the external clock terminals for timing the receipt of the write data by the data receivers of the IO circuit 122. The write data is supplied via the IO circuit 122 to RWAMP 120.

The semiconductor device 100 may also receive commands causing it to carry out one or more refresh operations as part of a self-refresh mode. In some embodiments, the self-refresh mode command may be externally issued to the semiconductor device 100. In some embodiments, the self-refresh mode command may be periodically generated by a component of the device. In some embodiments, when an external signal indicates a self-refresh entry command, the refresh signal AREF may also be activated.

The power supply terminals are supplied with power supply potentials VDD and VSS. The power supply potentials VDD and VSS are supplied to an internal voltage generating circuit 124. The internal voltage generating circuit 124 generates various internal potentials, such as VPP, VOD, VARY, VPERI, VBLP, and the like, based on the power supply potentials VDD and VSS, for supplying various voltages to be used in the semiconductor device 100. VPP may be used in the row decoder 108. VOD and VARY may be used in the sense amplifiers SAMP in the memory array 118. VPERI may be a peripheral power supply used in peripheral circuit blocks. VBLP may be a precharge voltage with a half-level potential or an intermediate potential. For example, while VDD may be 1.1V or 1.2V and VSS may be 0V (ground reference), VARY may be equal to or less than 1.0V, and VBLP may be set to around half of VARY (VARY/2) that is equal to or less than 0.5V. The internal potentials and their values are not limited to those described herein and may include other potentials and values as appropriate. The internal voltage generating circuit 124 may also be referred to as an internal voltage generator. The internal voltage generating circuit 124 may include a charge pump circuit.

The power supply terminals are also supplied with power supply potential VDDQ. The power supply potential VDDQ is supplied to the IO circuit 122. The power supply potential VDDQ may be the same potentials as the power supply potential VDD in one embodiment of the disclosure. The power supply potential VDDQ may be different potentials from the power supply potential VDD in another embodiment of the disclosure. The power supply potential VDDQ are used for the IO circuit 122 so that power supply noise generated by the IO circuit 122 does not propagate to the other circuit blocks.

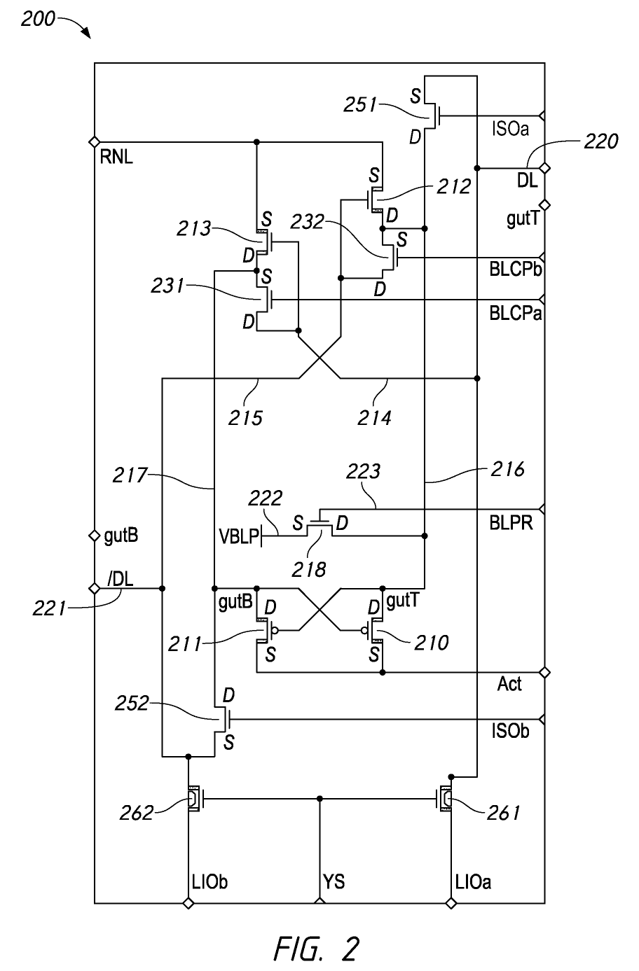

FIG. 2 is a circuit diagram of at least part of an example sense amplifier 200 according to some embodiments of the disclosure. The sense amplifier 200 may be included in one or more of the sense amplifiers SAMP of FIG. 1. The sense amplifier 200 may include transistors 210, 211 of a first type (e.g. p-type or p-channel field effect transistors (PFET), such as pMISFET or pMOSFET) having drains D coupled to drains D of transistors 212, 213 of a second type (e.g., n-type or n-channel field effect transistors (NFET), such as nMISFET or nMOSFET), respectively. The transistors 210 and 211 and the transistors 212 and 213 form complementary transistor inverters that include a first inverter including the transistors 210 and 212 and a second inverter including the transistors 211 and 213. The transistors 210 and 211 may be coupled to at sources S a Psense amplifier control line (e.g., an activation signal ACT), which may provide a supply voltage (e.g., an array voltage VARY) at an active “high” level. The transistors 212 and 213 may be coupled to at sources S an Nsense amplifier control line (e.g., a Row Nsense Latch signal RNL) that may provide a reference voltage (e.g., a ground voltage/VSS) at an active “low” level.

The sense amplifier 200 may sense and amplify the data state applied to sense nodes (or sense lines) 214 and 215 through complementary digit (or bit) lines DL and/DL (which may also be referred to as DLT and DLB) 220 and 221, respectively. Nodes 216 and 217 may be complementary gut nodes (or gut lines) gutT and gutB, the former commonly coupled to the drains D of the transistors 210 and 212 of the first inverter of the complementary transistor inverters, and the latter commonly coupled to the drains D of the transistors 211 and 213 of the second inverter of the complementary transistor inverters. The gut nodes gutT 216 and gutB 217 are also coupled to gates of the transistors 211 and 210, respectively. The gut nodes gutT 216 and gutB 217 may be coupled to the digit lines DL 220 and /DL 221 via isolation transistors 251 and 252, respectively. The isolation transistors 251 and 252 may be controlled by complementary isolation control signals ISOa and ISOb (which may also be referred to as ISOT and ISOB), respectively. When the isolation transistor 251 turns on in response to the isolation control signal ISOa, the isolation transistor 251 connects the digit line DL to the gut node gutT 216. When the isolation transistor 252 turns on in response to the isolation control signal ISOb, the isolation transistor 252 connects the digit line DL/ to the gut node gutB 217. On the other hand, the isolation transistors 251 and 252 disconnect the digit lines DL and DL/ from the gut nodes gutT 216 and gutB 217 in response to the isolation control signals ISOa and ISOb, respectively, to isolate the sense amplifier 200 from the digit lines DL 220 and DL/ 221.

The digit lines DL 220 and /DL 221 and the sense nodes 214 and 215 may be coupled to local input/output lines LIOa and LIOb through transistors 261 and 262 of the second type, respectively, which may be rendered conductive when a column select signal YS supplied to gates is active. When the transistors 261 and 262 turns on in response to the active column select signal YS, the transistors 261 and 262 connects the digit lines DL and /DL to the local input/output lines LIOa and LIOb, respectively. LIOa and LIOb may correspond to the LIOT/B lines of FIG. 1, respectively.

The sense amplifier 200 may further include additional transistors 231, 232 of the second type that have drains D coupled to the sense nodes 214 and 215, respectively, and sources S coupled to both the gut nodes gutB 217 and gutT 216 and the drains D of the transistors 213 and 212, respectively. Gates of the transistors 231 and 232 may receive complementary bit (digit) line compensation signals BLCPa and BLCPb, respectively, and may provide voltage compensation for threshold voltage (Vt) imbalance between the transistors 213 and 212.

The sense amplifier 200 may further include a transistor 218 of the second type having a drain D coupled to the gut node gutT 216 and a source S coupled to a precharge voltage line 222 to be supplied with a bit (digit) line precharge voltage (e.g., VBLP). A gate of the transistor 218 is coupled to a precharge control line 223 to receive a precharge control signal BLPR.

In operation, the sense amplifier 200 may be configured to sense a data state of a coupled memory cell on the digit lines (which may also be referred to as data lines) DL 220 and /DL 221 in response to received control signals (e.g., the ISOa/ISOb isolation signals, the ACT and RNL signals, the YS signal, and the BLCPa/BLCPb signals). The control signals may be provided by a decoder circuit, such as any of a command decoder (e.g., the command decoder 106 of FIG. 1), a row decoder (e.g., the row decoder 108 of FIG. 1), a column decoder (e.g., the column decoder 110 of FIG. 1), memory array control circuitry (e.g., control circuitry of the memory cell array of the memory banks BANK0-N of FIG. 1), or any combination thereof.

With respect to isolation transistors (hereinafter referred to as ISO transistors) of a sense amplifier (e.g., 251 and 252 of 200 in FIG. 2), in some instances, during a standby phase, the ISO transistors may receive at gates a high standby voltage of, for example, about 1.5V. The standby voltage level of the ISO transistors may be the highest among the other transistors of the sense amplifier. This high standby voltage may cause a large leak current at the gates of the respective ISO transistors. Therefore, in some instances, to address such high gate leak current, the ISO standby level may be adjusted to a lower voltage level of, for example, about 1.1V during a standby phase, while maintaining the high voltage level during a sense phase. This effectively reduces the gate leak current at the ISO transistors and hence achieves lower current consumption.

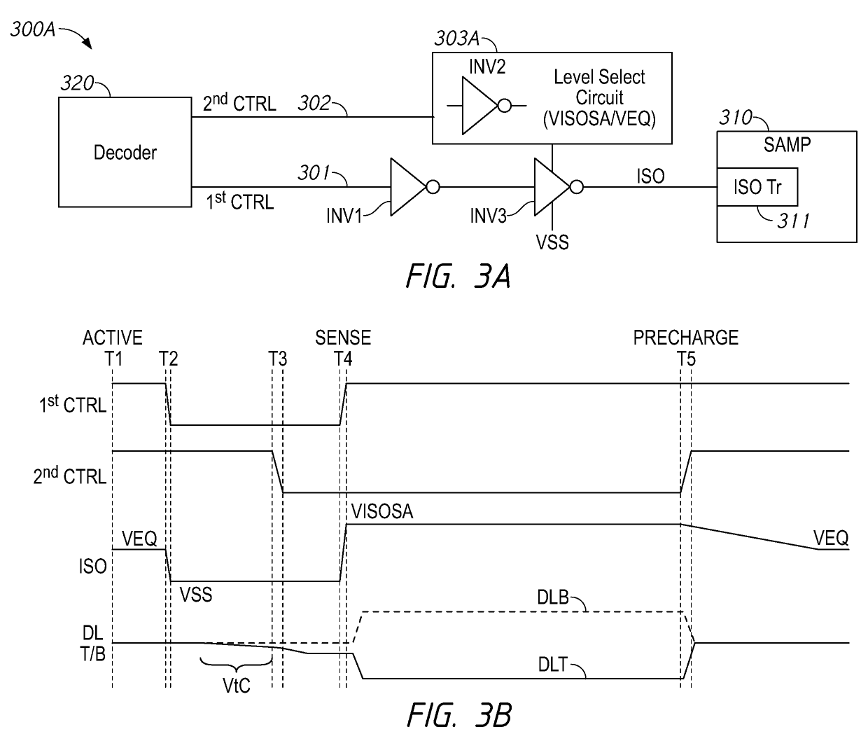

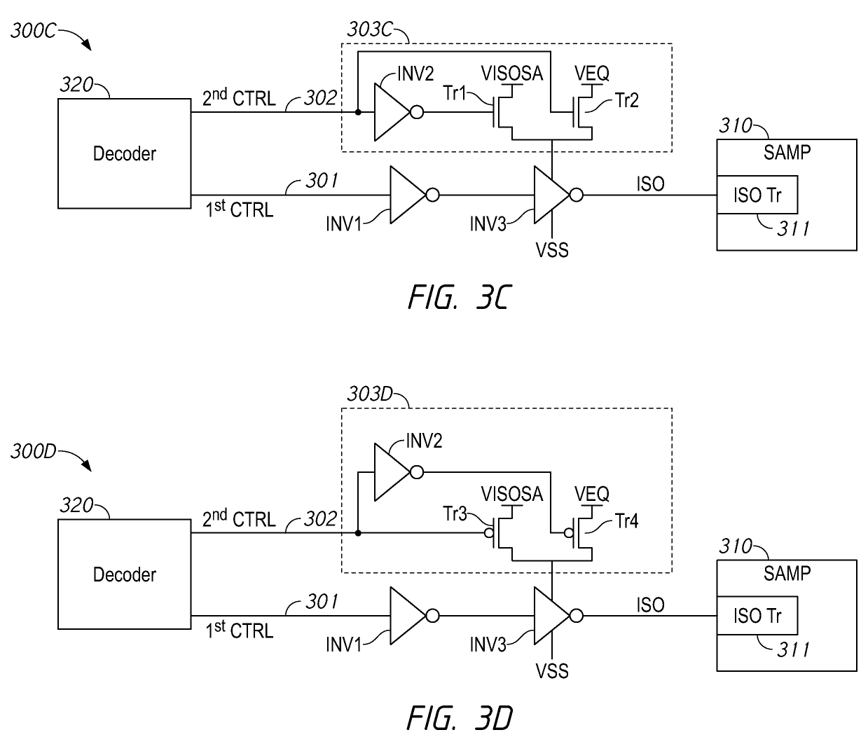

FIG. 3A is a schematic diagram of at least part of an example apparatus 300A according to some embodiments of the disclosure. FIG. 3B is a timing diagram of an ISO voltage level operation according to some embodiments of the disclosure. The apparatus 300A includes a first control signal path 301 that provides an ISO control signal to an ISO transistor 311 at its gate (see for example the complementary ISO control signals ISOa, ISOb and the isolation transistors 251, 252 of FIG. 2) of a sense amplifier SAMP 310 in response to a first control signal (1^{st} CTRL) and a second control signal path 302 that provides to the first signal path a first voltage and a second voltage, which may serve as a first standby voltage and a second standby voltage of the ISO transistor, respectively, in response to a second control signal (2^{nd} CTRL). While the first control signal path 301 outputs the ISO control signal to the ISO transistor 311 in response to the first control signal, the second control signal path 302 selects the standby voltage level of the ISO control signal in response to the second control signal. 1^{st} CTRL and 2^{nd} CTRL may be provided by a decoder circuit 320. The decoder circuit 320 may be a row decoder (e.g., the row decoder 108 of FIG. 1), or any other internal decoder circuits, memory array control circuitry, or any combination thereof. 1^{st} CTRL and 2^{nd} CTRL may be controlled in response to command signals and/or clock signals provided by an external device. The second voltage is lower than the first voltage. As shown in FIG. 3B, the ISO control signal has the first voltage (hereinafter referred to as VISOSA) during a sense phase (e.g., at a sense timing or timing T4) and the second voltage (hereinafter referred to as VEQ) during a standby phase (e.g., at a precharge timing or timing T5). Therefore, the ISO transistor 311 has its gate at the first voltage (VISOSA) level during the sense phase and at the second voltage (VEQ) level lower than the first voltage level during the standby phase in response to the ISO control signal. As one example, VISOSA may be around 1.5V, and VEQ may be around 1.1V. The values of VISOSA and VEQ are not limited to this example. VISOSA and VEQ (that is lower than VISOSA) can take any values as appropriate, depending on circuit designs, specifications, and the like. In some instances, the greater the difference between VISOSA and VEQ, the more effectively the gate leak current at the ISO transistors is reduced. VISOSA and VEQ may be generated by an internal voltage generator (e.g., the internal voltage generating circuit 124 of FIG. 1).

The apparatus 300A includes one or more inverters INV1, INV3 on the first control signal path 301 coupled to the ISO transistor 311 of the sense amplifier (hereinafter simply referred to as SAMP) 310. The configuration of the first control signal path 301 is not limited to the depicted examples; there may be other inverters and/or circuit elements as appropriate. The apparatus 300A includes a level select circuit 303A on the second control signal path 302 coupled to one of the inverters INV1, INV3, which is on an output side of the first control signal path, to supply VISOSA and VEQ as a source voltage of a transistor (not separately depicted) of the output-side inverter (that is INV3 in the depicted example). The level select circuit 303A receives the second control signal and in response selects VISOSA during the sense phase and VEQ during the standby phase. The second control signal thus serves as a level select signal. The level select circuit 303A may include for example one or more inverters INV2; however, the configuration of the level select circuit 303A is not limited to the depicted examples. In some instances, the level select circuit 303A may select VISOSA in response to the second control signal/level select signal at a first level during the sense phase and VEQ in response to the level select signal at a second level during the standby phase. At the inverter INV3 on the first signal path, in response to the first control signal at a first level, the inverter output as the ISO control signal is pulled to the source voltage, which may be VISOSA or VEQ supplied from the level select circuit 303A. When the level select circuit 303A provides VISOSA, the inverter INV3 outputs the ISO control signal at VISOSA, whereas when the level select circuit 303A provides VEQ, the inverter INV3 outputs the ISO control signal at VEQ lower than VISOSA. On the other hand, in response to the first control signal at a second level, the inverter output as the ISO control signal is pulled to VSS/ground.

FIG. 3C is a schematic diagram of at least part of an example apparatus 300C according to some embodiments of the disclosure. FIG. 3D is a schematic diagram of at least part of an example apparatus 300D according to some embodiments of the disclosure. FIGS. 3C and 3D depict variations of the level select circuit 303A.

In FIG. 3C, the level select circuit 303C of the apparatus 300C includes an inverter INV2 and a pair of first and second n-channel transistors (e.g., nMOS/nMIS FET) Tr1, Tr2. The n-channel transistors Tr1 and Tr2 are supplied with VISOSA and VEQ at sources, respectively. The n-channel transistors Tr1 and Tr2 have drains coupled to a source of the inverter INV3 on the first control signal path. A gate of the n-channel transistor Tr1 is coupled to an output node of the inverter INV2. The inverter INV2 receives the second/level control signal (2^{nd} CTRL) at its input and outputs the inverted signal to the Tr1 gate. A gate of the n-channel transistors Tr2 is coupled to a separate line coupled to a main line of the second control signal path to receive 2^{nd} CTRL.

In one instance, on the second control signal path, when 2^{nd} CTRL is Low, the inverted output signal from the inverter INV2 is High and turns on the n-channel transistor Tr1, which in response outputs VISOSA to the inverter INV3. On the first control signal path, when the first control signal (1^{st}CTRL) is Low (while 2^{nd} CTRL is Low), the inverted output signal from the inverter INV1 is High, and in response, the inverter INV3 pulls its output signal as the ISO control signal to VSS rather than VISOSA. This operation corresponds to timing T3 in FIG. 3B. When 1^{st} CTRL turns High (while 2^{nd} CTRL is Low), the inverter INV3 pulls the ISO control signal to VISOSA in response to the inverted 1^{st} CTRL Low from the inverter INV3. This operation corresponds to timing T4 in FIG. 3B. Turning of 1^{st} CTRL to the High level may be triggered by an active command and its clock signal. For example, 1^{st} CTRL may turn high at the sense timing controlled by the decoder circuit 320 in response to the active command and clock signal. The ISO control signal is maintained at VISOSA until timing T5 or the precharge timing.

In another instance, on the second control signal path, when 2^{nd} CTRL turns High, the n-channel transistors Tr2 turns on and outputs VEQ to the inverter INV3. On the first control signal path, when 1^{st} CTRL is Low (while 2^{nd} CTRL is High), the inverted output signal from the inverter INV1 is High, and in response, the inverter INV3 pulls the ISO control signal to VSS. This operation corresponds to timing T2 in FIG. 3B. Timing T2 may occur before a threshold voltage compensation (VtC) operation (see for example the BLCPa/BLCPb signals and the relevant transistors of the sense amplifier 200 in FIG. 2). When 1^{st} CTRL is High (while 2^{nd} CTRL is High), the inverter INV3 pulls the ISO control signal to VEQ in response to the inverted 1^{st} CTRL Low from the inverter INV3. This operation corresponds to timing T5 in FIG. 3B. Turning of 2^{nd} CTRL to the High level may be triggered by a precharge command and its clock signal. For example, 2^{nd} CTRL may turn high at the precharge timing controlled by the decoder circuit 320 in response to the precharge command and clock signal. The VEQ level is maintained at least until an active operation of the next cycle (timing T1). The VEQ level may also be maintained during the active operation until the next timing, such as timing T2 before VtC. Timings T1-T5 may be internally controlled based on various command signals which are decoded and provided by the decoder circuit 320, or any other internal decoder circuits, control circuitry, or any combination thereof.

Similarly to the level select circuit 303C of the apparatus 300C in FIG. 3C, the level select circuit 303D of the apparatus 300D in FIG. 3D includes a pair of first and second transistors Tr3 and Tr4 that receive VISOSA and VEQ at sources, respectively; however, the transistors Tr3 and Tr4 are p-channel transistors (e.g., pMOS/pMIS FET) unlike the n-channel transistors Tr1 and Tr2 in FIG. 3C. Moreover, the inverter INV2 is provided on the line coupled to the gate of the p-channel transistor Tr4 which receives the inverted 2^{nd} CTRL, whereas the p-channel transistor Tr3 directly receives 2^{nd} CTRL. Drains of the p-channel transistors Tr3 and Tr4 are coupled to the source of the inverter INV3 on the first control signal path. The level selection operation of the level select circuit 303D is similar to that of the level select circuit 303C, except that the High and Low levels are opposite due to the p-channel transistor operation. For instance, when 2^{nd} CTRL is Low, the p-channel transistor Tr3 turns on and outputs VISOSA to the inverter INV3, whereas when 2^{nd} CTRL is High, the inverted 2^{nd}CTRL Low turns on the p-channel transistor Tr4 to provide VEQ to the inverter INV3. Then, similarly to the inverter INV3 operation in FIG. 3C, when 1^{st} CTRL is High, the inverter INV3 outputs the ISO control signal at VISOSA (timing T4) and at VEQ (timing T5) in response to the inverted 1^{st}CTRL Low received from the inverter INV1, whereas when 1^{st}CTRL is Low, the inverter INV3 outputs the ISO control signal at VSS (timings T2 and T3) in response to the inverted 1^{st} CTRL High.

According to the present embodiments as described above, the ISO control signal becomes the VISOSA level during the sense phase and the VEQ level during the standby phase based on VISOSA and VEQ selected by the level select circuit 303, driving the gate of the ISO transistor 311 (e.g., the isolation transistors 251, 252 of FIG. 2) with VISOSA during the sense phase and VEQ during the standby phase, respectively. The apparatuses 300 of the present embodiments thus effectively reduce the gate leak current at the ISO transistors during the standby phase and achieve lower current consumption.

Furthermore, in the depicted examples, transitioning of the VISOSA level to the VEQ level during the standby phase or the precharge operation is conducted over a certain period of time, that is a settling time. More specifically, for example, at the start of the precharge operation, the ISO may still have the VISOSA level, and then as the precharge operation continues, the VISOSA level transitions to the VEQ level gradually over the settling time. The settling time may be set relatively long, such as a couple of hundreds of nanoseconds (ns). This is achieved by, for example, adjusting the size of the transistors Tr1, Tr2 (FIG. 3C) or Tr3, Tr4 (FIG. 3D), especially by making the size of the transistor Tr2 or Tr3 for VEQ small, without affecting the precharge operation.

In the above descriptions, DRAM is merely one example, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the apparatuses of the present embodiments. Furthermore, devices other than memory, including logic ICs, such as a microprocessor and an application- specific integrated circuit (ASIC), are also applicable as the apparatuses according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still falling within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising an isolation (ISO) transistor of a sense amplifier having a gate at a first voltage level during a sense phase and a second voltage level during a standby phase, the second voltage level lower than the first voltage level.

2. The apparatus according to claim 1, wherein the ISO transistor receives an ISO control signal at the gate, the ISO control signal having the first voltage level during the sense phase and the second voltage level during the standby phase.

3. The apparatus according to claim 2, further comprising a level select circuit configured to select the first voltage level during the sense phase and the second voltage level during the standby phase in response to a level select signal.

4. The apparatus according to claim 3, wherein the level select circuit selects the first voltage level in response to the level select signal at a first level during the sense phase and the second voltage level in response to the level select signal at a second level during the standby phase.

5. The apparatus according to claim 4, wherein the level select circuit comprises a first transistor and a second transistor, the first transistor having a source supplied with a first voltage and configured to output the first voltage in response to the level select signal at the first level, the second transistor having a source supplied with a second voltage and configured to output the second voltage in response to the level select signal at the second level, the second voltage less than the first voltage.

6. The apparatus according to claim 5, wherein the ISO control signal becomes the first voltage level based on the first voltage from the first transistor and the second voltage level based on the second voltage from the second transistor.

7. The apparatus according to claim 5, wherein the level select circuit provides the first voltage and the second voltage to a source of an inverter on a signal path of the ISO control signal, the inverter configured to output the ISO control signal based on the first voltage during the sense phase and based on the second voltage during the standby phase.

8. The apparatus according to claim 2, wherein the ISO control signal changes to the first voltage level at a sense timing and the second voltage level at a precharge timing.

9. The apparatus according to claim 8, wherein the first voltage level is maintained during a sense operation.

10. The apparatus according to claim 9, wherein the second voltage level transitions from the first voltage level during a precharge operation.

11. An apparatus, comprising:
a sense amplifier including an isolation (ISO) transistor configured to be coupled to a bit line and receive an ISO control signal at a gate thereof; and
a level select circuit configured to select a gate voltage level of the ISO transistor, wherein the level select circuit is configured to select a first voltage level during a sense phase and a second voltage level during a standby phase, the second voltage level lower than the first voltage level.

12. The apparatus according to claim 11, wherein the level select circuit selects the first voltage level and the second voltage level in response to a level select signal that turns a first level during the sense phase and a second level during the standby phase, respectively.

13. The apparatus according to claim 12, wherein the level select circuit comprises a first transistor configured to output a first voltage in response to the level select signal at the first level and a second transistor configured to output a second voltage in response to the level select signal at the second level, the second voltage less than the first voltage.

14. The apparatus according to claim 11, wherein the ISO control signal received at the gate of the ISO transistor has the first voltage level during the sense phase and the second voltage level during the standby phase.

15. The apparatus according to claim 14, wherein the ISO control signal maintains the first voltage level during a sense operation, and the ISO control signal transitions from the first voltage level to the second voltage level during a precharge operation after the sense operation.

16. An apparatus, comprising an isolation (ISO) transistor of a sense amplifier, wherein a gate voltage level of the ISO transistor is changed from a first voltage level to a second voltage level during a standby phase, the second voltage lower than the first voltage level.

17. The apparatus according to claim 16, wherein the gate voltage level is maintained at the first voltage level during the sense phase.

18. The apparatus according to claim 16, wherein the ISO transistor receives an ISO control signal at a gate, the ISO control signal has the first voltage level during the sense phase and the second voltage level during the standby phase.

19. The apparatus according to claim 16, wherein the first voltage level and the second voltage level are selected in response to a level select signal that is at a first level at a sense timing and a second level at a precharge timing, respectively.

20. The apparatus according to claim 16, further comprising a level select circuit including at least first and second transistors, the first transistor configured to output a first voltage in response to a level select signal that has a first level during a sense operation and a second voltage in response to the level select signal that has a second level during a precharege operation.
